(19) United States
(12) Patent Application Publication
(10) Pub. No.: US 2025/0003080 A1
(43) Pub. Date: Jan. 2, 2025

(54) PROCESS FOR PRODUCING COATED SUBSTRATES AND COATED SUBSTRATE AND USE THEREOF

(71) Applicant: FRAUNHOFER-GESELLSCHAFT ZUR FÖRDERUNG DER ANGEWANDTEN FORSCHUNG E.V., München (DE)

(72) Inventors: Kevin SCHUCK, Erlangen (DE); Felix STURM, Erlangen (DE); Christian REIMANN, Erlangen (DE); Jochen FRIEDRICH, Erlangen (DE)

(73) Assignee: FRAUNHOFER-GESELLSCHAFT ZUR FÖRDERUNG DER ANGEWANDTEN FORSCHUNG E.V., München (DE)

(21) Appl. No.: 18/293,885

(22) PCT Filed: Aug. 1, 2022
(86) PCT No.: PCT/EP2022/071558

§ 371 Date: Jan. 31, 2024

(30) Foreign Application Priority Data
Aug. 3, 2021 (EP) 21189473.8

(51) Int. Cl. C23C 24/10; C23C 16/448; C30B 25/08

(52) U.S. Cl. CPC C23C 24/103; C23C 16/4485; C30B 25/08

(57) ABSTRACT

The present invention relates to a process for producing coated substrates. In the process, first at least one region of a surface of a porous substrate is provided with at least one surface sealing layer. At least one aqueous suspension is then applied onto the at least one surface sealing layer, the at least one aqueous suspension containing at least one refractory metal carbide and water. The substrate is then subjected to a sintering process. The present invention also relates to a coated substrate, which can be produced or is produced by the method according to the invention, and to the use of such a coated substrate.

The present invention relates to a method of manufacturing coated substrates. Initially, at least one region of a surface of a porous substrate is provided with at least one surface sealing layer in the method. Then at least one aqueous suspension is applied to the at least one surface sealing layer, with the at least one aqueous suspension comprising at least one refractory metal carbide and water. The substrate is then subjected to a sintering process. The present invention further relates to a coated substrate that is or can be manufactured using the method in accordance with the invention and to the use of such a coated substrate.

Refractory metal carbides such as tantalum carbide (TaC) are generally characterized by their high mechanical, chemical and thermal resistance. The use of these materials focuses primarily on high-temperature applications, e.g. in semiconductor crystal growing, in which highly corrosive and aggressive species are present, thus limiting the usability of the existing component (e.g. made of graphite) or significantly reducing its service life. Since it is proving difficult to produce a proven volume component from refractory metal carbides at low cost and in complex geometry using the hot pressing processes described from the literature, coatings are preferably used. The process does not allow for production of ceramic layers via hot pressing. Coatings are produced via the CVD process, for example. Dense layers of a few micrometres are deposited onto a substrate via the gas phase. An example of this would be TaC coatings with a single-layer structure. However, this cost-intensive method prevents coated components with any geometries and sizes from being realized with an arbitrary layer thickness. To ensure greater flexibility in these areas, there is the option of applying the coatings to the substrate via a wet ceramic process (dipping, brushing or spraying). This can be achieved, for example, via a suspension based on organic solvents (see, for example, US 2013/0061800 A1). To produce the desired protective coating properties, a sintering process is added downstream of the application process via an initial suspension.

In addition to the generation of a mechanically stable coating by the final sintering process (high abrasion and adhesion resistance), a high degree of compaction is required at the same time in order to optimally protect the substrate from corrosive media in high-temperature applications. In addition to the requirement for a high degree of densification, it is also required that the formation of cracks in the coating after the sintering process is reduced to a minimum in order to ultimately ensure the protective coating properties of the refractory metal carbide coating and to maximally protect the base substrate from corrosive media in the high-temperature application. Cracks can occur during the sintering process, e.g. during the compaction or shrinkage process or also during cooling. The shrinkage cracks can be avoided by the fact that the applied green sheet show a uniform or homogeneously thick course and thus a uniform compaction can take place. In the case of inhomogeneities in the layer course (such as depressions), shrinkage cracks easily form, which can spread vertically or laterally in the further course of the sintering process or later also under operating conditions. Cracking during cooling is due to the release of excessive thermal tensile stresses induced by the usually large difference in thermal expansion coefficient between the refractory metal carbide coating and the base substrate.

The obtaining of a homogeneous layer extent is, however, made more difficult with the suspension-based coating of porous substrates such as CFC substrates by refractory metal carbide coatings due to the strong infiltration behavior of the porous substrates and the infiltration of the pores by the suspension that results therefrom and thus produces an inhomogeneous extent of the refractory metal carbide coatings.

Starting from this, it was the object of the present invention to provide a method of manufacturing coated substrates by which substrates can be obtained having a refractory metal carbide coating that extends as homogeneously as possible and that is as crack-free as possible. It was additionally the object of the present invention to provide coated substrates that have a refractory metal carbide coating that extends as homogeneously as possible and that is as crack-free as possible.

This object is achieved by the features of claim 1 with respect to a method of manufacturing coated substrates and by the features of claim 11 with respect to a coated substrate.

Possibilities of use of the coated substrate in accordance with the invention are set forth in claim 15. The dependent claims represent advantageous further developments.

A method of manufacturing coated substrates is thus provided in accordance with the invention in which
a) at least one region of a surface of a porous substrate is provided with at least one surface sealing layer;
b) at least one aqueous suspension is applied to the at least one surface sealing layer, with the at least one aqueous suspension comprising at least one refractory metal carbide and water; and
c) the substrate is subjected to a sintering process after step b).

In step a) of the method in accordance with the invention, first at least one region of a surface of a porous substrate is provided with at least one surface sealing layer. In this process, a region (or a part region) of the surface of the porous substrate or a plurality of regions (or a plurality of part regions) of the surface of the porous substrate or the entire surface of the porous substrate is/are provided with the at least one surface sealing layer. The at least one region of the surface of the porous substrate can be provided with a surface sealing layer or with a plurality of surface sealing layers.

The porous substrate may preferably be a carbon substrate, more preferably a graphite substrate, most preferably an iso-graphite substrate. In this context, iso-graphite is understood to mean graphite produced by the isostatic pressing process. The porous substrate can, for example, be a crucible, preferably a carbon crucible, particularly preferably a graphite crucible, very particularly preferably an iso-graphite crucible.

The pores of the porous layer preferably have a mean pore size in the range of 0.5 μm to 5 μm (preferably at the surface). The mean pore size (preferably at the surface) can be determined, for example, by means of mercury intrusion (DIN 66133:1993-06).

The pores of the porous substrate preferably have a mean pore inlet diameter in the range of 0.1 μm to 5 μm. The mean pore inlet diameter can be determined, for example, by means of mercury porosimetry (DIN 15901-1:2019-03).

The porous substrate preferably has an open porosity in the range of 5% to 20%. The open porosity can be determined, for example, by means of mercury intrusion (DIN 66133:1993-06).

In step b) of the method in accordance with the invention, at least one aqueous suspension is applied to the at least one surface sealing layer (applied in step a)). The at least one aqueous substrate can be applied to a part region or to a plurality of part regions of the at least one surface sealing layer or to the entire at least one surface sealing layer. The at least one aqueous suspension can be applied to the at least one surface sealing layer in layer form. The layer (or layers) of the at least one aqueous suspension applied in this manner can be called a green layer (or green layers). At least one layer of the at least one aqueous suspension is preferably applied to the at least one surface sealing layer in step b). The at least aqueous suspension comprises at least one refractory metal carbide and water in accordance with the invention. The at least one aqueous suspension can also consist of at least one refractory metal carbide. The at least one refractory metal carbide is preferably tantalum carbide.

The substrate is subjected to a sintering process in step c) of the method in accordance with the invention after step b). At least one protective layer including the at least one refractory metal carbide and composed of the at least one aqueous suspension (applied in step b)) can be manufactured by the sintering process. In other words, the at least one aqueous suspension (applied in step b)) can be converted into a protective layer that includes the at least one refractory metal carbide by the sintering process.

The method according to the invention enables the production of refractory metal carbide-based coatings on substrates that can serve as high-temperature and wear-resistant coatings or wear-resistant coating systems.

The method according to the invention is a wet ceramic process for the production of refractory metal carbide-based coatings on substrates. In contrast to coatings prepared via CVD or PVD processes, coatings prepared via wet ceramic processes exhibit an isotropic texture with random grain size orientation, resulting in reduced susceptibility to cracking and increased diffusion path for substrate-damaging species. Due to this, the coated substrates produced according to the invention exhibit improved protection against aggressive substances used in high-temperature applications compared to coated substrates produced via CVD or PVD processes. In addition, the wet ceramic process according to the invention is less expensive than CVD or PVD processes and also offers more flexibility in the geometries and sizes of the coated components that can be produced, as well as the layer thicknesses of the coatings or layers applied.

Furthermore, the method for producing coated substrates according to the invention is based on the use of an aqueous suspension. Compared to the use of organic suspensions, the use of aqueous suspensions has various advantages. Thus, in contrast to organic suspensions, aqueous suspensions are inexpensive, harmless from an ecological and health point of view, and also do not entail the safety-related problem of easily flammable spray mists. In addition, the use of aqueous suspensions eliminates the need for pyrolysis to remove organic solvents, which can lead to an undesirable introduction of foreign substances into the coating. Furthermore, in contrast to the use of the known organic suspensions, the use of aqueous suspensions allows for controlled application of the suspension. In particular, spray application of the known organic suspensions does not allow controlled application, since the suspension properties can fluctuate during this process due to evaporation of the solvent, so that homogeneous layers cannot be obtained over time.

Due to the sintering process, the protective coating obtained in the method according to the invention is a mechanically stable coating with high abrasion and adhesion resistance. In addition, a higher degree of compaction is achieved by the sintering process over the starting density after the application (green density).

The at least one surface sealing layer represents an intermediate layer between the porous substrate and the at least one protective layer that can be obtained in step c). Due to the at least one surface sealing layer, the pore inlets (of the pores of the porous substrate) that are located on the at least one region of the surface of the porous substrate can be substantially completely or at least almost completely closed. The surface of the at least one region is so-to-say sealed (or so-to-day almost sealed) in this manner. The at least one surface sealing layer can thus be at least one (substantially) closed surface sealing layer. Whether the pore inlets are substantially completely closed or at least almost completely closed can be determined by determining the gas permeability of the porous substrate in the region provided with the surface sealing layer, with the gas permeability e.g. being able to be determined by means of a pressure-dependent flow measurement in accordance with DIN EN 993-4:1995-04. If the measured gas permeability (e.g. by means of a pressure-dependent flow measurement in accordance with DIN EN 993-4:1995-04) amounts to 0 m², the pore inlets are substantially completely closed. The term “substantially” here means that a minimal permeability of the pore inlets may be present that is, however, not measurable (e.g. by means of a pressure-dependent flow measurement in accordance with DIN EN 993-4:1995-04). If the measured gas permeability (e.g. by means of a pressure-dependent flow measurement in accordance with DIN EN 993-4:1995-04) amounts to almost 0 m², the pore inlets are almost completely closed. The pore inlets are, for example, at least almost completely closed when the measured gas permeability (e.g. by means of a pressure-dependent flow measurement in accordance with DIN EN 993-4:1995-04) of the porous substrate in the region provided with the surface sealing layer amounts to a maximum of 1E-16 m² or the measured gas permeability (e.g. by means of a pressure-dependent flow measurement in accordance with DIN EN 993-4:1995-04) of the porous substrate in the region provided with the surface sealing layer amounts to a maximum of 10% of the measured gas permeability (e.g. by means of a pressure-dependent flow measurement in accordance with DIN EN 993-4:1995-04) of the porous substrate without a surface sealing layer. In other words, the pore inlets that are located on the at least one region of the surface of the porous substrate can be closed (almost completely) by the surface sealing layer such that the gas permeability of the porous substrate in the region provided with the surface sealing layer amounts to a maximum of 1E-16 m² or the gas permeability of the porous substrate in the region provided with the surface sealing layer amounts to a maximum of 10% of the gas permeability of the porous substrate without a surface sealing layer. The gas permeability of the porous substrate in the region provided with the surface sealing layer very particularly preferably amounts to a maximum of 0 m².

Since the pore inlets (of the pores of the porous substrate) that are located on the at least one region of the surface of the porous substrate are completely or at least almost completely closed by the surface sealing layer, the at least one aqueous suspension applied in step b) cannot enter or can only enter very slightly into the pores of the porous substrate. Since the at least one aqueous suspension is not applied directly to the porous substrate, but instead to the surface sealing layer, it is thus possible to prevent or at least substantially prevent the at least one aqueous suspension from entering into the pores of the porous substrate during the application in step b).

Without the use of a surface sealing layer, substantial amounts of the aqueous suspension would enter into the pores of the porous substrate on the application of the aqueous suspension to the porous substrate, which would result in inhomogeneities within the layer. In the event of such inhomogeneities in the layer extent (such as depressions), slight shrinkage cracks are formed that can propagate vertically and laterally in the further course of the sintering process or also later under conditions of use. The crack formation when cooling down is due to the reduction of thermal tensile stresses that are too high and that are induced by the typically great difference in the coefficient of thermal expansion between the refractory metal carbide coating and the base substrate (e.g. on a carbon base).

Due to the at least one surface sealing layer used in the method in accordance with the invention, a very homogeneous (or uniform) coating can now be obtained since a penetration of the aqueous suspension into the pores of the porous substrate can be prevented or can be at least substantially prevented by the at least one surface sealing layer. Shrinkage cracks within the protective layer can be avoided by the very homogeneous (or uniform) extent of the layer. This is also the case because the uniform or homogeneous course of the layer allows uniform compaction to take place. The fewer shrinkage cracks are present in the obtained protective layer, the better the substrate is protected by the protective layer (e.g. from corrosive media in high temperature applications). Due to the surface sealing layer used in accordance with the invention, a very homogeneous refractory metal carbide protective layer that is only slightly subject to cracks (or is even crack-free) can thus be obtained that can effectively protect the layer from external influences (such as from corrosive media in high temperature applications).

The coefficient of thermal expansion (CTE) of the at least one surface sealing layer is preferably adapted to the coefficient of thermal expansion of the porous substrate and/or to the coefficient of thermal expansion of the at least one protective layer.

Such an adaptation can, for example, take place by a selection of a material that is high temperature resistant, on the one hand, and simultaneously has a CTE that is between that of the protective layer and the substrate and by application of the adaptation layers by various coating processes, e.g. over the gas phase or over a spray sintering process. Since the coefficient of thermal expansion (CTE) of the at least one surface sealing layer is adapted to the coefficient of thermal expansion of the porous substrate and/or to the coefficient of thermal expansion of the at least one protective layer, CTE differences between the porous substrate and the at least one protective layer can be compensated and the thermal stresses or the extent of the thermally induced cracks can be minimized even further. The surface sealing layer can be utilized in dependence on the CTE difference between the protective layer and substrate in order to compensate or minimize a large CTE difference-above all when high thermally induced stresses provide that great crack formation or even delamination occurs after the sintering and the protective layer properties are thereby not ensured.

At least one layer of the at least one aqueous suspension is preferably applied to the at least one surface sealing layer in step b). The at least one layer of aqueous suspension can be called at least one green layer. The green layer or green layers can display a uniform or homogeneously thick extent.

The coated substrate that can be produced by the method according to the invention can be used, for example, as a gallium evaporator or part of a gallium evaporator in a VPE GaN reactor that can be used for growing gallium nitride semiconductor crystals, with the layer system obtained in the process according to the invention then acting as a coating for the gallium evaporator.

A preferred variant of the method according to the invention is characterized in that
the porous substrate comprises or consists of a material that is selected from the group consisting of graphite, preferably iso-graphite, carbon fiber reinforced carbon (CFC), C/SiC fiber composite materials, SiC/SiC fiber composite materials, carbidic ceramics, nitridic ceramics, oxidic ceramics, and mixtures thereof; and/or
the at least one refractory metal carbide is selected from the group consisting of titanium carbides, zirconium carbides, hafnium carbides, vanadium carbides, niobium carbides, tantalum carbides, chromium carbides, molybdenum carbides, tungsten carbides, and mixtures thereof.

Particularly preferably, the at least one refractory metal carbide is tantalum carbide. Tantalum carbide enables a particularly good protective effect for the porous substrate.

The porous substrate may preferably include or consist of a material selected from the group consisting of graphite, preferably iso-graphite, carbidic ceramics, nitridic ceramics, oxidic ceramics, and mixtures thereof.

The porous substrate may preferably contain or consist of a material selected from the group consisting of graphite, preferably iso-graphite, carbon fiber reinforced carbon (CFC), C/SiC fiber composites, SiC/SiC fiber composites, and mixtures thereof.

Carbon-based substrates and SiC-based substrates show increased infiltration behaviour when an aqueous suspension is applied. As a consequence, the method according to the invention is particularly suitable for such substrates.

Most preferably, the porous substrate contains or consists of graphite, preferably iso-graphite.

In accordance with a further preferred variant of the method in accordance with the invention, the at least one refractory metal carbide is present in the at least one aqueous suspension in particle form, with the mean particle size (d50 value) of the particles of the at least one refractory metal carbide being in the range from 0.2 μm to 2 μm, preferably from 0.5 μm to 1.5 μm. The mean particle size (d50 value) of the particles of the at least one refractory metal carbide can be determined, for example, by laser diffraction (DIN 13320:2020-01).

A further preferred embodiment of the method in accordance with the invention is characterized in that the pore inlets that are located on the at least one region of the surface of the porous substrate are closed so densely by the surface sealing layer that
the gas permeability of the porous substrate in the region provided with the surface sealing layer amounts to a maximum of 1E-16 m², preferably a maximum of 1E-17 m², particularly preferably a maximum of 5E-17 m², very particularly preferably 0 m²; and/or
the gas permeability of the porous substrate in the region provided with the surface sealing layer amounts to a maximum of 10%, preferably a maximum of 1%, particularly preferably a maximum of 0.5%, of the gas permeability of the porous substrate without a surface sealing layer.

The gas permeability can e.g. be determined by means of a pressure-dependent flow measurement in accordance with DIN EN 993-4:1995-04.

In accordance with a further preferred variant of the method in accordance with the invention, the at least one surface sealing layer is selected from the group consisting of pyrolytic carbon layers, silicon carbide layers, silicon layers, zirconium boride layers, tantalum nitride layers, silicon nitride layers, tungsten carbide layers, and combinations thereof.

A further preferred variant of the method in accordance with the invention is characterized in that the porous substrate is provided with at least one surface sealing layer in step a) in that
at least a portion of the surface of the porous substrate is impregnated with at least one polymerizable resin and the resin is subsequently carbonized; and/or
at least a portion of the surface of the porous substrate is impregnated with at least one polysilane and the polysilane is subsequently pyrolyzed; and/or
the pores of the porous substrate are infiltrated with silicon and the silicon is optionally converted at least partly into silicon carbide; and/or
at least one layer selected from the group consisting of layers of pyrolytic carbon, silicon carbide layers, silicon nitride layers, tungsten carbide layers, and combinations thereof is deposited on the porous substrate by means of CVD; and/or
a suspension comprising tungsten carbide is applied to at least a portion of the surface of the porous substrate and is subsequently subjected to a sintering process; and/or
at least one layer selected from the group consisting of silicon layers, zirconium boride layers, tantalum nitride layers, and combinations thereof is deposited on the porous substrate by means of a spray process.

There are various preferred possibilities of providing the porous substrate with the at least one surface sealing layer in step a).

The porous substrate can, for example, be provided with at least one surface sealing layer in step a) in that at least a portion of the surface of the porous substrate is impregnated with at least one polymerizable resin and the resin is subsequently carbonized. It is further preferred in this respect that
the impregnating with the at least one polymerizable resin takes place in that a solution comprising the at least one polymerizable resin is applied once or multiple times to the at least one portion of the surface; and/or
the at least one polymerizable resin is selected from the group consisting of polyimides, polybenzimidazoles, bismaleides, polyarylketones, polyphenylene sulfides (in solution), and mixtures thereof; and/or
the carbonization takes place by a heat treatment at a temperature of 20° C. to 400° C.; and/or
the coefficient of thermal expansion of the porous substrate is smaller than the coefficient of thermal expansion of the at least one protective layer, with the difference between the coefficient of thermal expansion of the porous substrate and the coefficient of thermal expansion of the at least one protective layer preferably being smaller than 1 e⁻⁶/K.

In accordance with a further preferred variant, the porous substrate can be provided with at least one surface sealing layer in step a) in that at least a portion of the surface of the porous substrate is impregnated with at least one polysilane and the polysilane is subsequently pyrolyzed. It is further preferred in this respect that
the impregnating with the at least one polysilane takes place in that a solution comprising the at least one polysilane is applied once or multiple times to the at least one portion of the surface; and/or
the at least one polysilane is selected from the group consisting of polycarbosilanes, polysiloxanes, polysilazanes, and mixtures thereof; and/or
the pyrolysis takes place by a heat treatment at a temperature of 20° C. to 1800° C.; and/or
the coefficient of thermal expansion of the porous substrate is smaller than the coefficient of thermal expansion of the at least one protective layer, with the difference between the coefficient of thermal expansion of the porous substrate and the coefficient of thermal expansion of the at least one protective layer preferably being smaller than 1 e⁻⁶/K.

In accordance with a further preferred variant, the porous substrate can be provided with at least one surface sealing layer in step a) in that the pores of the surface of the porous substrate are infiltrated with silicon and the silicon is at least partly converted into silicon carbide. It is further preferred in this respect that
the infiltrating with silicon and the at least partial conversion of the silicon into silicon carbide takes place in that a suspension comprising silicon is applied to the porous substrate and the applied suspension is subjected to a sintering process at a temperature greater than 1420° C., with the infiltration process (i.e. the infiltrating with silicon) preferably being integrated in the sintering process (i.e. in the sintering process at a temperature greater than 1420° C.); and/or
the obtained surface sealing layer has a layer thickness in the range from 5 μm to 300 μm, preferably 5 μm to 100 μm; and/or
after a partial conversion of the silicon into silicon carbide, the non-converted silicon is removed, preferably by grinding and/or milling; and/or
the coefficient of thermal expansion of the porous substrate is smaller than the coefficient of thermal expansion of the at least one protective layer, with the difference between the coefficient of thermal expansion of the porous substrate and the coefficient of thermal expansion of the at least one protective layer preferably being greater than 2 e⁻⁶/K.

In accordance with a further preferred variant, the porous substrate can be provided with at least one surface sealing layer in step a) in that at least one layer selected from the group consisting of pyrolytic carbon, silicon carbide layers, silicon nitride layers, tungsten carbide layers, and combinations thereof is deposited on the porous substrate by means of CVD. It is preferred in this respect that the deposition tykes place on the porous substrate by means of CVD in that reactive gas species (e.g. CH₃SiCl₃, H₂, etc. for the manufacture of CVD-SiC) move onto the surface of the porous substrate and a chemically binding surface sealing layer is preferably formed (at the porous substrate) at temperatures in the range from 800° C. to 1400° C.

In accordance with a further preferred variant, the porous substrate can be provided with at least one surface sealing layer in step a) in that a suspension comprising tungsten carbide is applied to at least a portion of the porous substrate and is subsequently subjected to a sintering process. It is further preferred in this respect that
the sintering process is carried out at a temperature of more than 2000° C.; and/or
the coefficient of thermal expansion of the porous substrate is smaller than the coefficient of thermal expansion of the at least one protective layer, with the difference between the coefficient of thermal expansion of the porous substrate and the coefficient of thermal expansion of the at least one protective layer preferably being smaller than 2 e⁻⁶/K.

A further preferred variant of the method in accordance with the invention is characterized in that the difference between the coefficient of thermal expansion of the porous substrate and the coefficient of thermal expansion of the at least one refractory metal carbide layer is determined before step a) and a suitable method of providing the porous substrate with at least one surface sealing layer in step a) is selected with reference to this difference.

The selection of surface sealing layers follows the coefficient of thermal expansion (CTE) of the substrate to be coated or the difference in CTE between the substrate and the protective layer. The reason for this is that the thermal stress on the coating during a thermal sintering cycle is determined by the CTE difference (Therm. Stress^{˜}ΔCTE*ΔT).

Cracks can occur during this process. This means that if the CTE difference is <0.8E-6/K, the layers remain crack-free, if the CTE difference is <2.5E-6/K the layers are only slightly cracked.

The composition of the sealing layer is therefore selected in such a way that the CTE of the sealed substrate is matched as closely as possible to the CTE of the layer. This is illustrated by the following examples:
for CTE (substrate)>5.8E-6/K: sealing with PyC, ZrB2 or TaB2 and mixtures thereof
for CTE (substrate)>4E-6/K: sealing by SiC layer, ZrB2, TaB2 and mixtures thereof
for CTE (substrate)>1.5E-5/K: sealing by Si layer, SiC, ZrB2, TaB2 and mixtures thereof

In accordance with a further preferred variant of the method in accordance with the invention, the coefficient of thermal expansion of the porous substrate is smaller than the coefficient of thermal expansion of the at least one protective layer, with the difference between the coefficient of thermal expansion of the porous substrate and the coefficient of thermal expansion of the at least one protective layer being greater than 2 e⁻⁶/K or smaller than 1 e⁻⁶/K.

A further preferred variant of the method in accordance with the invention is characterized in that the at least one aqueous suspension
comprises 60 to 90 wt %, preferably 70 to 85 wt %, of the at least one refractory metal carbide, relative to the total weight of the aqueous suspension; and/or
comprises 0.01 to 0.5 wt % of a dispersion agent relative to the total weight of the aqueous suspension, with the dispersion agent preferably being selected from the group consisting of polyvinyl alcohols; polyacrylic acids; polyvinylpyrrolidones; polyalkylene gly-colethers; bases, preferably tetrabutylammonium hydroxide, tetramethylammonium hydroxide, polyethyleneimines, inorganic bases, in particular NaOH, ammonium hydroxide; and mixtures thereof, more preferably selected from the group consisting of ammonium hydroxide, polyalkelene glycolether, and mixtures thereof; and/or
comprises 0.01 to 5 wt % of a binding agent relative to the total weight of the aqueous suspension, with the binding agent preferably being selected from the group consisting of polyethylene glycol, polyvinyl butyral, polyurethanes, chloroprene rubber, phenolic resins, acrylic resins, carboxymethyl celluloses, alginic acid, dextrins, sodium biphenyl-2-yloxides, polyphenyloxide, and mixtures thereof, more preferably selected from the group consisting of sodium biphenyl-2-yloxides, polyphenyl oxide, and mixtures thereof; and/or
is manufactured by mixing its components with the aid of a dispersion device, with the mixing preferably taking place with the aid of the dispersion device while using grinding elements and/or over a time period of at least 12 hours.

An optimum intermixing of the aqueous suspension can be achieved by mixing the components with the aid of a dispersion device while preferably using grinding elements and/or over a time period of at least 12 hours so that inhomogeneities in the distribution and thus in the compaction can be avoided even more. Revolution speeds of up to 1 m/s can, for example, be used in the mixing with the dispersion device.

The at least one aqueous suspension can comprise at least one binding agent selected from the group consisting of polyethylene glycol, polyvinyl butyral, polyurethanes, chloroprene rubber, phenolic resins, acrylic resins, carboxymethyl celluloses, alginic acid, dextrins, sodium biphenyl-2-yloxides, polyphenyloxide, and mixtures thereof, more preferably selected from the group consisting of sodium biphenyl-2-yl oxides, polyphenyl oxide, and mixtures thereof, wherein the at least one binding agent can preferably be comprised in the at least one aqueous suspension at a proportion of 0.05 to 1 wt % or of 0.01 to 5 wt % relative to the total weight of the aqueous suspension.

In accordance with a preferred embodiment variant, the at least one aqueous suspension can comprise a sintering additive that is preferably selected from the group consisting of refractory metal silicides, refractory metal nitrides, refractory metal borides, silicon, silicon carbide, boron nitride, tungsten carbide, vanadium carbide, molybdenum carbide, boron carbide and mixtures thereof, wherein the sintering additive is particularly preferably selected from the group consisting of silicon, zirconium boride, refractory metal carbides, and mixtures thereof.

The refractory metal silicides are preferably selected from the group consisting of titanium silicides, zirconium silicides, e.g. zirconium disilicide (ZrSi2), hafnium silicides, e.g. hafnium disilicide (HfSi2), vanadium silicides, e.g. vanadium disilicide (VSi2), niobium silicides, e.g. niobium disilicide (NbSi2), tantalum silicides, e.g. tantalum disilicide (TaSi2), chromium silicides, molybdenum silicides, e.g. molybdenum disilicide (MoSi2), tungsten silicides, e.g. tungsten disilicide (WSi2), and mixtures thereof.

The refractory metal nitrides are preferably selected from the group consisting of titanium nitrides, zirconium nitrides, hafnium nitrides, vanadium nitrides, niobium nitrides, tantalum nitrides, chromium nitrides, molybdenum nitrides, tungsten nitrides, and mixtures thereof.

The refractory metal borides are preferably selected from the group consisting of titanium borides, zirconium borides, hafnium borides, vanadium borides, niobium borides, tantalum borides, chromium borides, molybdenum borides, tungsten borides and mixtures thereof.

These sintering additives have been shown to have at least the same or even a better effect on the degree of densification than the transition metals (e.g. cobalt, nickel, iron, etc.) used as sintering additives in the prior art, due to their properties (e.g. melting points, boiling points, etc.). Thus, a high degree of densification of the sintered layer can be achieved by using them, which protects the substrate very well from corrosive media in high-temperature applications. Compared with the sinter additives used in the prior art, such as cobalt, the sinter additives mentioned are characterized first of all by the fact that they are harmless in terms of safety and health. It is additionally prevented by its use and thus by the avoidance of specific transition metals, like cobalt, nickel, iron, as sintering additives that these transition metals are retained in the layer as a contamination, which would be damaging to the growing atmosphere there on a use of the coated substrate in high temperature applications in semiconductor crystal growing.

In accordance with a further preferred variant of the method in accordance with the invention, the application of the at least one aqueous suspension takes place by means of dipping, brushing, and/or spray application in step b). The application of the at least one aqueous suspension particularly preferably takes place by means of spray application in step b). Spray application is the preferred choice for the production of one or more thin, fast-drying refractory metal carbide coatings, preferably with layer thicknesses in the range of 20 μm to 80 μm. In this process, a very thin suspension layer can be applied to the surface by rapidly rotating the component through the spray jet. Depending on the solids content of the suspension, this layer can dry quickly to very quickly. Preferred solids contents of the refractory metal carbide powder are greater than or equal to 70% by weight of the total suspension. Each individual layer to be applied should preferably show comparable drying behaviour. A fast-drying behavior of the applied suspension layers is generally preferred since density differences between the refractory metal carbide and the sintering additive can result in an inhomogeneity in the distribution of the particles if the layers dry for too long.

At least one layer of the aqueous suspension can preferably be applied to the at least one surface sealing layer in step b) with a mean layer thickness of 20 μm, preferably of 20 μm to 150 μm, particularly preferably from 30 μm to 100 μm.

A further preferred variant of the method in accordance with the invention is characterized in that the sintering process in step c) takes place
at a temperature of 2100° C. to 2500° C., preferably of 2200° C. to 2400° C.; and/or
with a holding time of 1 hour to 15 hours, preferably of 2 hours to 10 hours, and/or
at a pressure of 0.1 bar to 10 bar, preferably 0.7 bar to 5 bar, and/or
under argon atmosphere.

On the one hand, these designs of the sintering process can ensure that the protective coating obtained has a particularly high mechanical stability with a particularly high abrasion and adhesion resistance. The stability of the melting phase over the entire sintering process is additionally increased by these designs of the sintering process.

The present invention further relates to a coated substrate comprising a porous substrate, at least one surface sealing layer arranged on at least one region of the surface of the porous substrate, and at least one protective layer that is arranged on the at least one surface sealing layer and that comprises at least one refractory metal carbide.

Due to the at least one surface sealing layer, the at least one protective layer can be obtained very inhomogeneously and only slightly subject to cracks (or even crack free) so that the at least one protective layer can better protect the porous substrate from foreign influences (such as from corrosive media in high temperature applications).

Due to the at least one surface sealing layer, the pore inlets (of the pores of the porous substrate) that are located on the at least one region of the surface of the porous substrate can be completely or at least almost completely closed.

It is possible that the protective layer disposed on the at least one surface sealing layer does not comprise hafnium carbide and/or zirconium carbide.

For example, the at least one surface sealing layer comprises tantalum carbide and does not comprise any other refractory metal carbide. The at least one surface sealing layer may comprise tantalum carbide.

Preferably, the protective layer disposed on the at least one surface sealing layer does not comprise refractory metal boride.

A preferred embodiment of the coated substrate in accordance with the invention is characterized in that the at least one protective layer arranged on the at least one surface sealing layer has a mean layer thickness of at least 20 μm, preferably of 20 μm to 150, particularly preferably of 30 μm to 100 μm.

In accordance with a further preferred embodiment of the coated substrate in accordance with the invention, the standard deviation of the at least one protective layer is below 6%, preferably in the range of 0.5% to 6% particularly preferably in the range from 1% to 6%.

The standard deviation of the mean layer thickness is a measure for the homogeneity (or uniformity) of the layer thickness of the layer. The smaller the standard deviation of the mean layer thickness of the at least one protective layer, the more homogeneous (or more uniform) the layer thickness of the at least one protective layer also is.

The optical extent of the at least one protective layer can be presented and evaluated in a classical manner using a cross-section polish. An optical observation of the cross-section polish and the qualitative classification in a homogeneous or inhomogeneous layer system can take place here.

The mean layer thickness of the at least one protective layer can likewise be determined using cross-section polishes of the coated substrate. The mean layer thickness is thus determined in that a plurality of point measurements are carried out at the layer cross-section polish, from which a standard deviation can then be calculated that additionally delivers a quantitative estimate of the homogeneity of the layer extent.

For example, quantification of homogeneity using the standard deviation of the layer thickness is possible in the following way:
preparation of a transverse section of coated substrate (i.e. layer+substrate)
measurement of the distance between interface and layer surface (layer thickness) on the basis of recorded cross-section images
layer thickness analysis in an area with maximum extension of e.g. 4 cm
number of individual layer thickness measurements is at least 25 per 1 cm of measuring area
spacing of individual layer thickness measurements is regular
determination of the standard deviation over all individual layer thickness measurements
For example, with a standard deviation of ≤6%, it can be assumed that the layer in question is homogeneous.

A fast, qualitative statement on the homogeneity of the layer can already be made with reference to the plan view without carrying out a complex cross-section polish preparation.

It is further preferred that the at least one surface sealing layer is selected from the group consisting of pyrolytical carbon layers silicon carbide layers, silicon nitride layers, tungsten carbide layers, and combinations thereof.

It is further preferred that
the porous substrate comprises or consists of a material that is selected from the group consisting of graphite, preferably iso-graphite, carbon fiber reinforced carbon (CFC), C/SiC fiber composite materials, SiC/SiC fiber composite materials, carbidic ceramics, nitridic ceramics, oxidic ceramics, and mixtures thereof; and/or
the at least one refractory metal carbide is selected from the group consisting of titanium carbides, zirconium carbides, hafnium carbides, vanadium carbides, niobium carbides, tantalum carbides, chromium carbides, molybdenum carbides, tungsten carbides, and mixtures thereof.

Particularly preferably, the at least one refractory metal carbide is tantalum carbide.

The porous substrate may preferably include or consist of a material selected from the group consisting of graphite, preferably iso-graphite, carbidic ceramics, nitridic ceramics, oxidic ceramics, and mixtures thereof.

The porous substrate may preferably contain or consist of a material selected from the group consisting of graphite, preferably iso-graphite, carbon fiber reinforced carbon (CFC), C/SiC fiber composites, SiC/SiC fiber composites, and mixtures thereof.

Most preferably, the porous substrate contains or consists of graphite, preferably iso-graphite.

The porous substrate may preferably be a carbon substrate, more preferably a graphite substrate, most preferably an iso-graphite substrate. In this context, iso-graphite is understood to mean graphite produced by the isostatic pressing process. The porous substrate can, for example, be a crucible, preferably a carbon crucible, particularly preferably a graphite crucible, very particularly preferably an iso-graphite crucible.

The coefficient of thermal expansion (CTE) of the at least one surface sealing layer is preferably adapted to the coefficient of thermal expansion of the porous substrate and/or to the coefficient of thermal expansion of the at least one protective layer. In this manner, CTE differences between the porous substrate and the at least one protective layer can be compensated and the thermal stresses or the size of the thermally induced cracks can consequently be even further minimized. The surface sealing layer can be utilized in dependence on the CTE difference between the protective layer and substrate in order to compensate or minimize a large CTE difference-above all when high thermally induced stresses provide that great crack formation or even delamination occurs after the sintering and the protective layer properties are thereby not ensured.

It is additionally preferred that the coefficient of thermal expansion of the porous substrate is smaller than the coefficient of thermal expansion of the at least one protective layer, with the difference between the coefficient of thermal expansion of the substrate and the coefficient of thermal expansion of the at least one protective layer being greater than 2 e⁻⁶/K or smaller than 1 e⁻⁶/K.

A further preferred embodiment of the coated substrate in accordance with the invention is characterized in that the coated substrate can be or is manufactured using the method in accordance with the invention.

Furthermore, the present invention also relates to the use of the coated substrate according to the invention in semiconductor crystal growing, wherein the coated substrate is preferably a coated crucible.

The present invention will be explained in more detail with reference to the following Figures and examples without restricting the invention to the specifically shown parameters.

### EMBODIMENT 1

The surface of a porous graphite substrate (mean pore diameter: 1.8 μm, grain size: 10 μm, Rₐ: 1.5 μm) is provided with a surface sealing layer in that the pores of the porous substrate are infiltrated with silicon and the silicon is at least partly converted into silicon carbide. Fine silicon fractions are for this purpose applied to the surface of the porous graphite substrate and are subsequently subjected to a heat treatment at a temperature of 1500° C. for a duration of 5 h in a vacuum atmosphere. The surface sealing layer obtained thereon is a silicon carbide layer.

An aqueous suspension is then applied in layer form to the surface sealing layer obtained, with the aqueous suspension consisting of 80 wt % TaC powder, 0.1 wt % tetrabutylammonium hydroxide, 1 wt % polyvinyl alcohol, and 18.9 wt % water. The substrate provided with the aqueous suspension is subsequently subjected to a sintering process that takes place at a temperature of 2300° C., with a dwell time of 10 h and at a pressure of 1 bar.

A coated graphite substrate is obtained in this manner that comprises a porous graphite substrate, a silicon carbide surface sealing layer arranged on the porous graphite substrate, and a TaC protective layer arranged on the silicon carbide surface sealing layer.

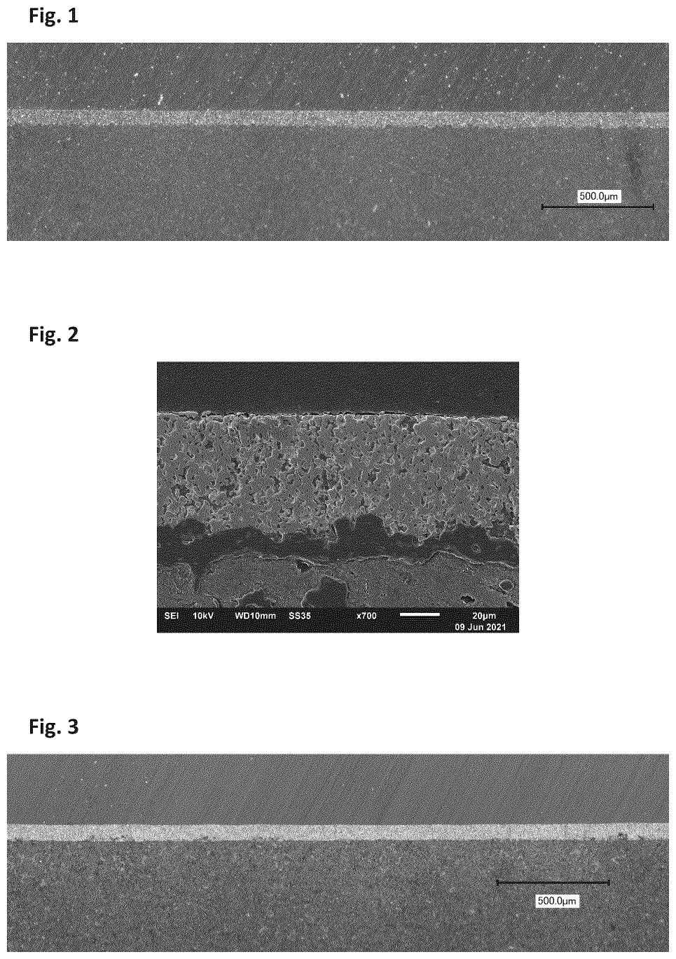

A cross-section polish of the coated substrate is produced to analyze the coated substrate. An image of this cross-section polish is shown in FIG. 1. FIG. 2 additionally shows an REM recording of the cross-section polish.

The mean layer thickness of the TaC layer and the standard deviation of the mean layer thickness are determined with reference to the cross-section polish. For this purpose, layer thickness individual measurements are made at at least 25 measurement points per 1 cm measurement range in that the distance between the border surface and the layer surface (layer thickness) is measured with reference to recorded cross-section polish images, with the intervals between the individual measurement points being regular. A value of 64.8 μm is determined for the mean layer thickness of the TaC layer in this manner. In addition, a standard deviation over all the layer thickness individual measurements of 3.3 μm (5.1%) is determined.

Since the standard deviation does not exceed 6%, the TaC layer is therefore a homogeneous layer.

### EMBODIMENT 2

The surface of a porous graphite substrate (mean pore diameter: 1.8 μm, grain size: 10 μm, Rₐ: 1.5 μm) is provided with a surface sealing layer in that the pores of the porous substrate are infiltrated with silicon and the silicon is at least partly converted into silicon carbide. Coarse silicon powder is for this purpose applied to the surface of the porous graphite substrate and are subsequently subjected to a heat treatment at a temperature of 1500° C. for a duration of 5 h in a vacuum atmosphere. The surface sealing layer obtained thereon is a silicon carbide layer.

An aqueous suspension is then applied in layer form to the surface sealing layer obtained, with the aqueous suspension consisting of 80 wt % TaC powder, 0.1 wt % tetrabutylammonium hydroxide, 1 wt % polyvinyl alcohol, and 18.9 wt % water. The substrate provided with the aqueous suspension is subsequently subjected to a sintering process that takes place at a temperature of 2300° C., with a dwell time of 10 h and at a pressure of 1 bar.

A coated graphite substrate is obtained in this manner that comprises a porous graphite substrate, a silicon carbide surface sealing layer arranged on the porous graphite substrate, and a TaC protective layer arranged on the silicon carbide surface sealing layer.

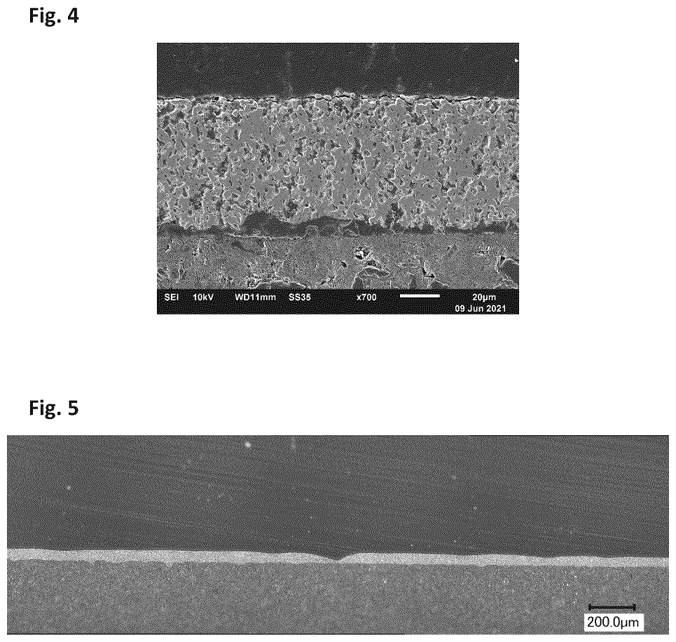

A cross-section polish of the coated substrate is produced to analyze the coated substrate. An image of this cross-section polish is shown in FIG. 3. FIG. 4 additionally shows an REM recording of the cross-section polish.

The mean layer thickness of the TaC layer and the standard deviation of the mean layer thickness are determined with reference to the cross-section polish. For this purpose, layer thickness individual measurements are made at at least 25 measurement points per 1 cm measurement range in that the distance between the border surface and the layer surface (layer thickness) is measured with reference to recorded cross-section polish images, with the intervals between the individual measurement points being regular. A value of 75.3 μm is determined for the mean layer thickness of the TaC layer in this manner. In addition, a standard deviation over all the layer thickness individual measurements of 3.5 μm (4.7%) is determined.

Since the standard deviation does not exceed 6%, the TaC layer is therefore a homogeneous layer.

### COMPARISON EXAMPLE

An aqueous suspension is applied in layer form to a porous graphite substrate (mean pore diameter: 1.8 μm, grain size: 10 μm, Rₐ: 1.5 μm) that does not have any surface sealing layer, with the aqueous suspension consisting of 80 wt % TaC powder, 0.1 wt % tetrabutylammonium hydroxide, 1 wt % polyvinyl alcohol, and 18.9 wt % water. The substrate provided with the aqueous suspension is subsequently subjected to a sintering process that takes place at a temperature of 2300° C., with a dwell time of 10 h and at a pressure of 1 bar.

A coated graphite substrate is obtained in this manner that comprises a porous graphite substrate and a TaC protective layer arranged on the porous graphite substrate, but no surface sealing layer arranged between the substrate and the protective layer.

A cross-section polish of the coated substrate is produced to analyze the coated substrate. An image of this cross-section polish is shown in FIG. 5.

The mean layer thickness of the TaC layer and the standard deviation of the mean layer thickness are determined with reference to the cross-section polish. For this purpose, layer thickness individual measurements are made at at least 25 measurement points per 1 cm measurement range in that the distance between the border surface and the layer surface (layer thickness) is measured with reference to recorded cross-section polish images, with the intervals between the individual measurement points being regular. A value of 44.7 μm is determined for the mean layer thickness of the TaC layer in this manner. In addition, a standard deviation over all the layer thickness individual measurements of 5.3 μm (11.8%) is determined.

Since the standard deviation amounts to more than 6%, the TaC layer is thus an inhomogeneous layer.

1-15. (canceled)

16. A method of producing a coated substrate, the method comprising:
a) providing at least one surface sealing layer on at least one region of a surface of a porous substrate;
b) applying at least one aqueous suspension to the at least one surface sealing layer, with the at least one aqueous suspension comprising at least one refractory metal carbide and water; and
c) subjecting the substrate to a sintering process after step b).

17. The method in accordance with claim 16, wherein
the porous substrate comprises a material selected from the group consisting of graphite, a carbon fiber reinforced carbon (CFC), a C/SiC fiber composite material, a SiC/SiC fiber composite material, a carbidic ceramic, a nitridic ceramic, an oxidic ceramic, and mixtures thereof; and/or
the at least one refractory metal carbide is selected from the group consisting of titanium carbide, zirconium carbide, hafnium carbide, vanadium carbide, niobium carbide, tantalum carbide, chromium carbide, molybdenum carbide, and tungsten carbide.

18. The method in accordance with claim 16, wherein the at least one refractory metal carbide is present in the at least one aqueous suspension in particle form, with the mean particle size (d50 value) of particles of the at least one refractory metal carbide is in a range from 0.2 μm to 2 μm.

19. The method in accordance with claim 16, wherein pore inlets that are located on the at least one region of the surface of the porous substrate are closed so densely by the surface sealing layer that
the gas permeability of the porous substrate in the region provided with the surface sealing layer amounts to a maximum of 1E-16 m²; and/or
the gas permeability of the porous substrate in the region provided with the surface sealing layer amounts to a maximum of 10% of the gas permeability of the porous substrate without a surface sealing layer.

20. The method in accordance with claim 16, wherein the at least one surface sealing layer is selected from the group consisting of pyrolytical carbon layers, silicon layers, zirconium boride layers, tantalum nitride layers, silicon carbide layers, silicon nitride layers, and tungsten carbide layers.

21. The method in accordance with claim 16, wherein the porous substrate is provided with at least one surface sealing layer in step a) by impregnating at least a portion of the surface of the porous substrate with at least one polymerizable resin and subsequently carbonizing the resin; and/or
impregnating at least a portion of the surface of the porous substrate with at least one polysilane and subsequently pyrolyzing the polysilane; and/or
infiltrating the pores of the porous substrate with silicon and converting the silicon at least partly into silicon carbide; and/or
at least one layer selected from the group consisting of layers of pyrolytic carbon, silicon carbide layers, silicon nitride layers, and tungsten carbide layers is deposited on the porous substrate by CVD; and/or
a suspension comprising tungsten carbide is applied to at least a portion of the surface of the porous substrate and is subsequently subjected to a sintering process; and/or
at least one layer selected from the group consisting of silicon layers, zirconium boride layers, and tantalum nitride layers is deposited on the porous substrate by a spray process.

22. The method in accordance with claim 16, wherein the difference between the coefficient of thermal expansion of the porous substrate and the coefficient of thermal expansion of the at least one refractory metal carbide layer is determined before carrying out step a) and a suitable method of providing the porous substrate with at least one surface sealing layer in step a) is selected with reference to this difference.

23. The method in accordance with claim 16, wherein the at least one aqueous suspension
comprises 60 to 90 wt % of the at least one refractory metal carbide, relative to the total weight of the aqueous suspension; and/or
comprises 0.01 to 0.5 wt % of a dispersion agent relative to the total weight of the aqueous suspension, and/or
comprises 0.01 to 5 wt % of a binding agent relative to the total weight of the aqueous suspension, and/or
is manufactured by mixing its components with the aid of a dispersion device.

24. The method in accordance with claim 16, wherein the application of the at least one aqueous suspension in step b) takes place by dipping, brushing, and/or spray application.

25. The method in accordance with claim 16, wherein the sintering process in step c) takes place
at a temperature of from 2100° C. to 2500° C., and/or
with a holding time of 1 hour to 15 hours, and/or
at a pressure of 0.1 bar to 10 bar, and/or
under argon atmosphere.

26. The method in accordance with claim 23, wherein the dispersion agent is selected from the group consisting of polyvinyl alcohols, polyacrylic acids, polyvinylpyrrolidones, polyalkylene glycolethers, bases, and mixtures thereof.

27. The method in accordance with claim 23, wherein the binding agent is selected from the group consisting of polyethylene glycol, polyvinyl butyral, polyurethanes, chloroprene rubber, phenolic resins, acrylic resins, carboxymethyl celluloses, alginic acid, dextrins, sodium biphenyl-2-yloxides, polyphenyloxide, and mixtures thereof.

28. The method in accordance with claim 23, wherein the mixing takes place with the aid of the dispersion device including grinding elements and/or over a time of at least 12 hours.

29. A coated substrate comprising a porous substrate, at least one surface sealing layer arranged on at least one region of the surface of the porous substrate, and at least one protective layer that is arranged on the at least one surface sealing layer and that comprises at least one refractory metal carbide.

30. The coated substrate in accordance with claim 29, wherein the at least one protective layer has a mean layer thickness of at least 20 μm.

31. The coated substrate in accordance with claim 29, wherein a standard deviation of the mean layer thickness of the at least one protective layer is below 6%.

32. A coated substrate prepared in accordance with claim 16.

33. A method of growing semiconductor crystals comprising growing the semiconductor crystals in a coated crucible which is a coated substrate in accordance with claim 29.
